(19) United States
(12) Patent Application Publication
(10) Pub. No.: US 2025/0107266 A1
(43) Pub. Date: Mar. 27, 2025

(54) LIGHT EMITTING DIODE UNIT FOR HARVESTING ENERGY AND DISPLAY MODULE

(71) Applicant: Samsung Electronics Co., Ltd., Suwon-si (KR)

(72) Inventor: Taeyoung KIM, Suwon-si (KR)

(21) Appl. No.: 18/975,750

(22) Filed: Dec. 10, 2024

Related U.S. Application Data
(63) Continuation of application No. PCT/KR2023/009410, filed on Jul. 4, 2023.

(30) Foreign Application Priority Data
Aug. 8, 2022 (KR) 10-2022-0098812

(51) Int. Cl. H01L 31/173

(52) U.S. Cl. CPC H10F 55/255

(57) ABSTRACT

Disclosed are a light emitting diode unit for harvesting energy and a display module. The light emitting diode unit comprises: a substrate; a light emitting diode arranged on the substrate; and an energy harvesting member comprising a semiconductor layer surrounding the light emitting diode and configured to absorb light energy emitted by the light emitting diode, to generate electric energy, wherein an inner surface of the energy harvesting member is spaced apart from the light emitting diode.

### CROSS-REFERENCE TO RELATED APPLICATIONS

This application is a continuation of International Application No. PCT/KR2023/009410 designating the United States, filed on Jul. 4, 2023, in the Korean Intellectual Property Receiving Office and claiming priority to Korean Patent Application No. 10-2022-0098812, filed on Aug. 8, 2022, in the Korean Intellectual Property Office, the disclosures of each of which are incorporated by reference herein in their entireties.

### BACKGROUND

### Field

The disclosure relates to a light emitting diode unit for harvesting energy, and a display module.

### Description of Related Art

A display panel includes a substrate on which a plurality of thin film transistors (TFTs) are provided and a plurality of light emitting diodes mounted on the substrate. The plurality of light emitting diodes may be inorganic light emitting diodes which emit light by itself. The plurality of light emitting diodes operate in a pixel or subpixel unit and express various colors. An operation of each pixel or sub-pixel is controlled by various TFTs. Each light emitting diode emits various colors, for example, red, green, and blue.

### SUMMARY

According to an example embodiment, a light emitting diode unit includes: a substrate, a light emitting diode arranged on the substrate, and an energy harvesting member comprising a plurality of semiconductor layers surrounding the light emitting diode and configured to generate electric energy by absorbing light energy emitted from the light emitting diode. An inner side of the energy harvesting member may be arranged to be spaced apart from the light emitting diode.

A height of the energy harvesting member may be higher than a height of the light emitting diode. For example, the height of the energy harvesting member may twice or more the height of the light emitting diode.

The energy harvesting member may include a N-type semiconductor layer including the inner side of the energy harvesting member, and a P-type semiconductor layer including an outer side of the energy harvesting member and in contact with the N-type semiconductor layer.

An upper surface of the N-type semiconductor layer may form an entire upper surface of the energy harvesting member. Accordingly, the N-type semiconductor layer may increase an amount of absorption of external light.

A boundary surface of the N-type semiconductor layer and the P-type semiconductor layer of the energy harvesting member may be disposed in a diagonal direction.

The boundary surface of the N-type semiconductor layer and the P-type semiconductor layer of the energy harvesting member may be uneven in shape. The boundary surface of the N-type semiconductor layer and the P-type semiconductor layer of the energy harvesting member may be zigzag in shape.

The energy harvesting member may be polygonal when viewed in a plan view. The energy harvesting member may be a form of a closed curve when viewed in a plan view. The energy harvesting member may be circular or elliptical when viewed in a plan view.

The light emitting diode may be provided in multiple numbers. For example, the light emitting diode may be provided as three light emitting diodes respectively emitting red, green, and blue.

According to an example embodiment, the display module may be disclosed. The display module may include: a first substrate on which a plurality of thin film transistors are provided, and a plurality of light emitting diode units comprising a light emitting diode arranged on the first substrates. Each of the plurality of light emitting diode units may include a second substrate, a light emitting diode arranged on the second substrate, and an energy harvesting member comprising a semiconductor layer surrounding a side surface of the light emitting diode and spaced apart from the light emitting diode.

### BRIEF DESCRIPTION OF THE DRAWINGS

The above and other aspects, features and advantages of certain embodiments of the present disclosure will be more apparent from the following detailed description, taken in conjunction with the accompanying drawings, in which:

FIG.1 is a block diagram illustrating an example configuration of a display device according to various embodiments;

FIG. 2 is a diagram illustrating a plan view of a display module according to various embodiments;

FIG. 3 is a diagram illustrating a plan view of a light emitting diode unit according to various embodiments;

FIG. 4 is a longitudinal sectional view taken along line A-A′ in FIG. 3 according to various embodiments;

FIG. 5 is a diagram illustrating a circuit storing electric energy harvested by the light emitting diode unit according to various embodiments;

FIGS. 6, 7, 8, 9, 10, 11 and 12 are longitudinal sectional views illustrating the light emitting diode unit according to various embodiments;

FIG. 13 is a diagram illustrating a plan view of an example in which the energy harvesting member of the light emitting diode unit is formed in a circle according to various embodiments;

FIG. 14 is a diagram illustrating a plan view of an example in which the energy harvesting member of the light emitting diode unit is formed in a polygon according to various embodiments;

FIG. 15 is a diagram illustrating a plan view of the light emitting diode unit according to various embodiments;

FIG. 16 is a longitudinal sectional view taken along line B-B′ in FIG. 15 according to various embodiments;

FIG. 17 is a diagram illustrating a plan view of the light emitting diode unit according to various embodiments; and

FIG. 18 is a longitudinal sectional view taken along line C-C′ in FIG. 17 according to various embodiments.

### DETAILED DESCRIPTION

Hereinafter, various example embodiments are described in greater detail with respect to the attached drawings. The various embodiments described herein may be variously modified. A specific embodiment may be depicted in the drawings and be specifically described in the detailed description. However, the specific embodiments disclosed in the attached drawings are merely to help understanding of the various embodiments. Therefore, it is to be understood that the technical spirit is not limited by the specific embodiment disclosed in the attached drawings and encompasses all equivalents or substituents included in the scope of the spirit and technologies of the present disclosure.

In the present disclosure, the terms including ordinal numbers such as first and second may be used to describe various components, but these components are not limited by the aforementioned terms. The aforementioned terms are simply used to distinguish a component from another component.

It is to be understood that the terms such as “comprise” or “have” are used to designate presence of a characteristic, a number, an operation, a component, a part or a combination thereof, and not to preclude presence of or possibility of adding one or more other characteristics, numbers, steps, operations, components, parts or a combination thereof. It is to be understood that when it is noted that a component “is coupled” or “is connected” to another component, the component may be directly coupled or connected to another component, but the other component may be present therebetween. It is to be understood that when it is noted that a component “is directly coupled” or “is directly connected” to another component, the other component is not present therebetween.

In the present disclosure, the expression ‘same’ not only refers to complete matching but also includes difference in consideration of ranges of machining tolerance.

Besides, in describing the present disclosure, when it is determined that the detailed description of the related known function or configuration makes the gist of the present disclosure vague, the detailed description thereto may be shortened or omitted.

According to an embodiment, the display module may include a plurality of light emitting diodes for an image display. The display module may include a flat display panel or curved display panel.

According to an embodiment, the light emitting diode included in the display module may be an inorganic light emitting diode having a size of 100 μm or less. For example, the inorganic light emitting diode may be a micro LED or mini LED but is not limited thereto. Brightness, luminous efficiency, and a lifetime of the inorganic light emitting diode are longer than those of the organic light emitting diode (hereinafter, referred to as ‘OLED’). The inorganic light emitting diode may be a semiconductor chip which may emit light by itself when power is supplied. The inorganic light emitting diode has a rapid reaction speed, low power, and high luminance. When the inorganic light emitting diode is a micro LED, efficiency of converting electricity to a photon thereof may be higher than that of LCD or OLED. For example, “brightness per watt” of a micro LED may be higher than that of a LCD or OLED display. Accordingly, the micro LED may make the same brightness as the LED or OLED even with about half energy compared to more than 100 μm of the LED or OLED. The micro LED may realize high resolution, excellent color, light and shade, and brightness, and thus exactly express a wide range of colors and realize a clear screen even in an exterior brighter than an interior. The micro LED is resistant to burn-in and has a low heat-emitting temperature and thus a long lifetime thereof may be ensured without deformation.

According to an embodiment, the light emitting diode may be made in a form of a flip chip in which anode and cathode electrodes are disposed on an opposite side of a light emitting surface.

According to an embodiment, a TFT layer on which a TFT circuit is formed may be disposed on a first surface of the substrate (e.g. a front surface of the substrate). A power supply circuit supplying power to the TFT circuit, a data driving driver, a gate driving driver, and a timing controller of controlling each driving driver may be disposed on a second surface of the substrate (e.g. a rear surface of the substrate). A plurality of pixels are arranged on the TFT layer of the substrate. Each pixel may be driven by the TFT circuit.

According to an embodiment, a TFT of the TFT layer may be a low-temperature polycrystalline silicon (LTPS) TFT, a low-temperature polycrystalline oxide (LTPO) TFT, or an oxide TFT.

According to an embodiment, the substrate on which the TFT layer is provided may be a glass substrate, a synthetic resin based (e.g. polyimide (PI), polyethylene terephthalate (PET), polyethersulfone (PES), polyethylene naphthalate (PEN), polycarbonate (PC), etc.) substrate having flexibility, or a ceramic substrate.

According to an embodiment, the TFT layer of the substrate is formed to be integrated to the first surface of the substrate or is manufactured in a form of a separate film to be attached to the first surface of the substrate.

According to an embodiment, the first surface of the substrate may be divided into an active region and an inactive region. The active region may be a region occupied by the TFT layer in the entire region of the first surface of the substrate. The inactive region may be a region except the active region in the entire region of the first surface of the substrate.

According to an embodiment, edge regions of the substrate may be outermost regions of the substrate. For example, the edge regions of the substrate may include regions corresponding to sides of the substrate, partial regions of the first surface of the substrate adjacent to the sides, respectively, and partial regions of the second surface of the substrate. A plurality of side wiring of electrically connecting the TFT circuit on the first surface of the substrate and a drive circuit on the second surface of the substrate may be disposed on the edge regions of the substrate.

According to an embodiment, the substrate may be formed in a quadrangle type. For example, the substrate may be formed in a rectangle or square.

According to an embodiment, the TFT provided to the substrate may be also realized as for example, the oxide TFT, a Si TFT (poly silicon TFT, a-silicon TFT), an organic TFT, a graphene TFT, etc. other than the low-temperature polycrystalline silicon (LTPS) TFT. Only a P-type (or N-type) MOSFET of the TFT may be made and applied in a Si wafer CMOS process.

According to an embodiment, the TFT layer on which the TFT circuit is formed may be omitted from the substrate included in the display module. In this case, a plurality of micro IC chips having a role of the TFT circuit may be mounted on the first surface of the substrate. In this case, a plurality of micro ICs may be electrically connected to a plurality of light emitting diodes arranged on the first surface of the substrate through wiring.

According to an embodiment, a pixel driving method of the display module may be an active matrix (AM) driving method or a passive matrix (PM) driving method.

According to an embodiment, the display module may be installed in and applied to a wearable device, a portable device, a handheld device, and an electronic product or an electric box in which various displays are needed.

According to an embodiment, display devices such as a monitor for a personal computer, a high resolution television, signage (or digital signage), and an electronic display may be formed by connecting a plurality of display modules in a grid array.

According to an embodiment, one pixel may include a plurality of light emitting diodes. In this case, one light emitting diode may be a sub-pixel. In the present disclosure, one ‘light emitting diode’, one ‘micro LED’, and one ‘sub-pixel’ may be used to have the same meaning.

Hereinafter, various example embodiments are specifically described to be easily implemented by those skilled in the art with reference to the attached drawings. However, the various embodiments may be realized in various and different forms and the present disclosure is not limited to the embodiments described herein. To clearly describe the various embodiments of the present disclosure in the drawings, the part which is not related to the description of the disclosure may be omitted and similar parts are designated by similar reference numerals through the entire disclosure.

Hereinafter, the display device and the light emitting diode unit are described in greater detail with reference to the drawings.

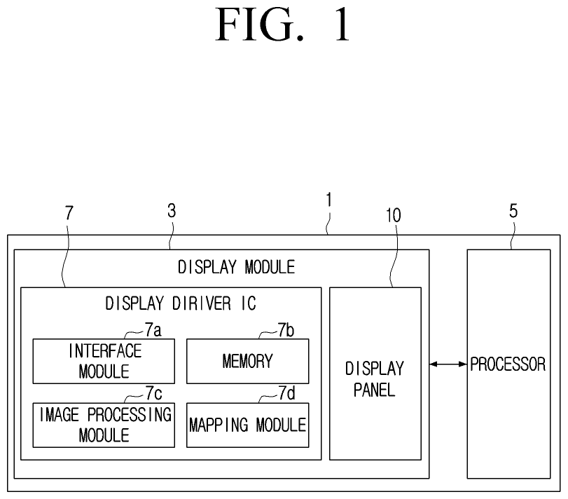

FIG.1 is a block diagram illustrating an example configuration of a display device according to various embodiments.

With reference to FIG. 1, a display device 1 may include a display module 3 and a processor (e.g., including processing circuitry) 5 according to an embodiment.

The display module 3 may display various images. Here, images may have a concept of including still images and/or moving images. The display module 3 may display various images such as broadcast contents, and multimedia contents. Also, the display module 3 may display a user interface and an icon.

The display module 3 may include a display panel 10 and a display driver integrated circuit (display driver IC) 7 for controlling the display panel 10.

The display driver IC 7 may include an interface module (e.g., including various circuitry) 7a, a memory 7b (e.g. buffer memory), an image processing module (e.g., including various circuitry) 7c, and/or a mapping module (e.g., including various circuitry and/or executable program instructions) 7d. The display driver IC 7 may receive, for example, image data or image information including an image control signal corresponding to a command for controlling the image data through the interface module 7a from another component of the display device 1. For example, the image information may be received from a processor 5 (e.g. a main processor (e.g. an application processor) or a peripheral processor (e.g. a graphic processing unit) independently operating from the main processor.

The display driver IC 7 may store at least part of the received image information in the memory 7b, for example, in a frame unit. The image processing module 7c, for example, may perform preprocessing or post processing (e.g. resolution, brightness or scale adjustment) of at least part of the image data based on characteristics of the image data or characteristics of the display panel 10. The mapping module 7d may generate a voltage value or a current value corresponding to the image data preprocessed or post processed through the image processing module 7c. According to an embodiment, generation of the voltage value or current value may be performed at least partially based on attributes of pixels (e.g. arrangement of pixels (a RGB stripe structure or RGB pentile structure) or a size of each sub-pixel) of the display panel 10. At least part of pixels of the display panel 10 may be driven at least partially based on, for example, the voltage value or current value and thus visual information (e.g. a text, an image, or an icon) corresponding to the image data may be displayed via the display panel 10.

The display driver IC 7 may transmit a driving signal (e.g. a driver driving signal, a gate driving signal, etc.) to the display based on image information received from the processor 5.

The display driver IC 7 may display images based on the image signal received from the processor 5. As an example, the display driver IC 7 may display images by generating a driving signal of a plurality of sub-pixels based on the image signal received from the processor 5 and controlling light emitting of the plurality of sub-pixels based on the driving signal.

The display module 3 may further include a touch circuit (not shown). The touch circuit may include a touch sensor and a touch sensor IC of controlling the touch sensor. The touch sensor IC, for example, may control the touch sensor so as to sense a touch input or a hovering input to a designated location of the display panel 10. For example, the touch sensor IC may sense the touch input or hovering input by measuring changes of signals (e.g. a voltage, an amount of light, resistance, or quantity of electric charge) to the designated location of the display panel 10. The touch sensor IC may provide information (e.g. a location, an area, pressure, or time) related to the sensed touch input or hovering input to the processor 5. According to an example, at least part of the touch circuit (e.g. the touch sensor IC) may be included as the display driver IC 7, part of the display panel 10, or another component (e.g. a peripheral processor) disposed outside the display module 3.

The processor 5 may include various processing circuitry and be realized as a digital signal processor (DSP), a microprocessor, a graphics processing unit (GPU), an artificial intelligence (AI) processor, a neural processing unit (NPU), and a time controller (TCON). The processor is not limited thereto and may include one or more of a central processing unit (CPU), a micro controller unit (MCU), a micro processing unit (MPU), a controller, an application processor (AP), a communication processor (CP), or an ARM processor, or may be defined by the relative terms. Also, the processor 5 may be realized by a system on chip (SoC) or large scale integration (LSI) in which processing algorism is embedded and may be implemented in a form of an application specific integrated circuit (ASIC) or a field programmable gate array (FPGA). The processor 5 may include various processing circuitry and/or multiple processors. For example, as used herein, including the claims, the term “processor” may include various processing circuitry, including at least one processor, wherein one or more of at least one processor, individually and/or collectively in a distributed manner, may be configured to perform various functions described herein. As used herein, when “a processor”, “at least one processor”, and “one or more processors” are described as being configured to perform numerous functions, these terms cover situations, for example and without limitation, in which one processor performs some of recited functions and another processor(s) performs other of recited functions, and also situations in which a single processor may perform all recited functions. Additionally, the at least one processor may include a combination of processors performing various of the recited/disclosed functions, e.g., in a distributed manner. At least one processor may execute program instructions to achieve or perform various functions.

The processor 5 may control hardware or software components connected to the processor 5 by driving an operating system or an application program and may perform various data processing and arithmetic operations. Also, the processor 5 may load a command or data received from at least one of other components onto a volatile memory and process it and then may store various data in a non-volatile memory.

The display module 3 may be a touch screen coupled to the touch sensor, a flexible display, a rollable display, and/or a three dimensional display.

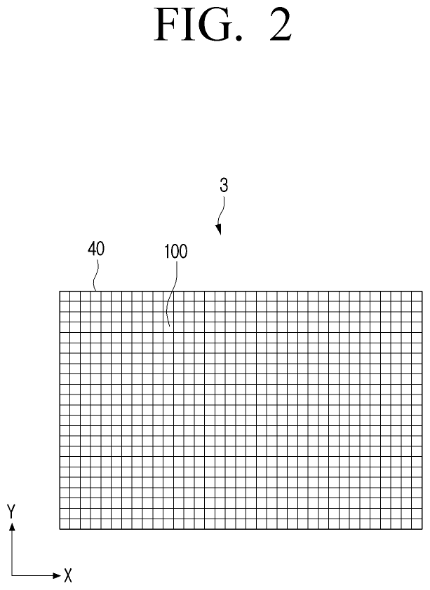

FIG. 2 is a diagram illustrating a plan view of a display module according to various embodiments.

With reference to FIG. 2, a display module 3 may include a substrate 40 and a plurality of pixels 100 provided to a first surface of the substrate 40.

The substrate 40 is provided with a thin film transistor (TFT) circuit which electrically connected to a plurality pixels 100 on the first surface thereof. The TFT provided to the substrate 40 may be an amorphous silicon (a-Si) TFT, a low temperature polycrystalline silicon (LTPS) TFT, a low temperature polycrystalline oxide (LTPO) TFT, a hybrid oxide and polycrystalline silicon (HOP) TFT, a liquid crystalline polymer (LCP) TFT, or an organic TFT (OTFT).

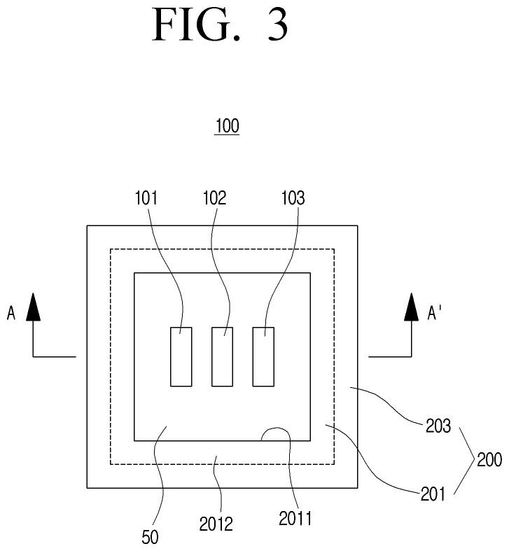

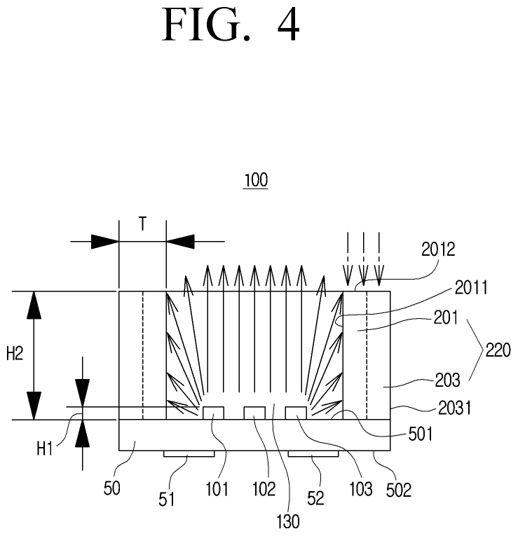

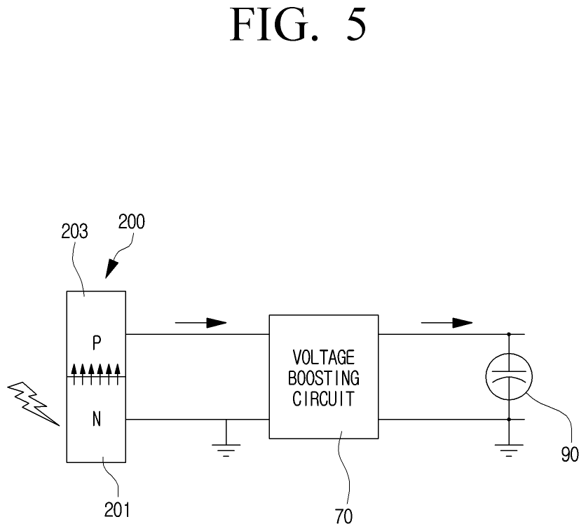

FIG. 3 is a diagram illustrating a plan view of a light emitting diode unit according to various embodiments. FIG. 4 is a longitudinal sectional view illustrating a light emitting diode taken along line A-A′ in FIG. 3 according to various embodiments. FIG. 5 is a diagram illustrating a circuit for storing electric energy harvested by the light emitting diode unit according to various embodiments.

According to an embodiment, one pixel 100 may correspond to one light emitting diode unit. Therefore, the reference numeral 100 designating ‘pixel’ may be used as the reference numeral designating the light emitting diode unit in the present disclosure. The light emitting diode unit 100 may be, for example, a light emitting diode package.

According to an embodiment, the light emitting diode unit 100 may include at least three sub-pixels. The sub-pixels may be, for example, a micro LED which is an inorganic light emitting diode. Hereinafter, the sub-pixel is referred to as the micro LED for convenience. Here, the micro LED may be defined as 100 μm or less or 30 μm or less of a LED in size.

With reference to FIGS. 3 and 4, the light emitting diode unit 100 may include a sub-substrate 50, three micro LEDs 101, 102, 103 arranged on the sub-substrate 50, an energy harvesting member 200 formed on the sub-substrate 50, and a light diffusing layer 130.

The three micro LEDs 101, 102, 103 may be mounted spaced apart on an upper surface 501 of the sub-substrate 50. The sub-substrate 50 may be a glass substrate, a synthetic resin based-flexible substrate (e.g. a polyimide (PI) substrate), or a ceramic substrate.

The light emitting diode unit 100 may include a first micro LED 101 emitting light of a red wavelength band, a second micro LED 102 emitting light of a green wavelength band, and a third micro LED 103 emitting light of a blue wavelength band. The light emitting diode unit 100 may include, for example, three micro LEDs 101, 102, 103 but is not limited thereto. For example, the light emitting diode unit 100 may include one micro LED or four micro LEDs.

The first micro LED 101, the second micro LED 102, and the third micro LED 103 may be arranged at regular intervals on the sub-substrate 50. A plurality of TFTs to drive the first to third micro LEDs 101, 102, 103 may be arranged on the sub-substrate 50. As the above, when the plurality of TFTs are arranged on the sub-substrate 50, the TFTs may be omitted from the substrate 40 on which a plurality of light emitting diode units 100 are mounted.

The first to third micro LEDs 101, 102, 103 may be arranged at regular intervals in a line on an upper surface of the sub-substrate 50 as shown in FIG. 3 but are not limited thereto. For example, the first to third micro LEDs 101, 102, 103 may be arranged in a form of L or be arranged in a pentile RGBG method. The pentile RGBG method is the method of arranging the number of sub-pixels of red, green and blue in a ratio of 1:1:2 (RGBG) using a cognitive characteristic that a human may identify green better than blue. The pentile RGBG method may increase a yield and decrease a unit cost. The pentile RGBG method may realize high resolution on a small screen.

A light emitting characteristic of the first micro LED 101 may be the same as that of the second and third micro LEDs 102, 103. Light emitted from the first micro LED 101 may be light having the same color as that of light emitted from the second and third micro LEDs 102, 103. Accordingly, solid color light of red, green or blue may be emitted or light mixed with red, green, or blue may be emitted from the light emitting diode unit 100.

With reference to FIG. 4, a plurality of electrode pads 51, 52 may be arranged on the lower surface 502 of the sub-substrate 50. Only two electrode pads are shown in FIG. 4 but the present disclosure is not limited thereto. For example, two electrode pads may correspond to one micro LED and at least two or more electrode pads connected to various signal lines of the substrate 40 (see FIG. 2) may be provided. In this case, at least eight or more electrode pads may be provided on the opposite surface of the sub-substrate 50.

The plurality of electrode pads 51, 52 of the sub-substrate 50 may be connected to a plurality of electrode pads (not shown) provided to the substrate 40 (see FIG. 2). In this case, the plurality of electrode pads 51, 52 of the sub-substrate 50 may be electrically and physically connected respectively to electrode pads of the substrate 40 by a solder. Also, the plurality of electrode pads 51, 52 of the sub-substrate 50 may be electrically and physically connected to a plurality of electrode pads of the substrate 40 by an anisotropic conductive film (ACF) or an anisotropic conductive paste (ACP) provided to the substrate 40.

The first micro LED 101 may have a form of a flip chip. For example, a pair of electrodes may be arranged on an opposite side of a light emitting surface of the first micro LED 101. The second micro LED 102 and the third micro LED 103 may substantially have the same form of a flip chip as that of the first micro LED 101. All sizes of the first to third micro LEDs may be the same but the present disclosure is not limited thereto. For example, at least one of the first to third micro LEDs 101, 102, 103 may have a size different from a size of the others.

With reference to FIG. 4, the light diffusing layer 130 may be laminated in a given thickness on the upper surface 501 of the sub-substrate 50. In this case, the light diffusing layer 130 may be formed using inkjet printing, screen printing, lamination, spin coating, sputtering, or chemical vapor deposition (CVD). For example, the light diffusing layer 130 may be formed by inserting a medium including fine particles into a space formed by the energy harvesting member 200, coating the upper surface 501 of the sub-substrate 50 with it in a given thickness, and curing it through heat curing and/or ultraviolet curing. The light diffusing layer 130 may be made of a transparent material.

The light diffusing layer 130 may improve luminance uniformity by diffusing light emitted from the first to third micro LEDs 101, 102, 103. The light diffusing layer 130 covers the first to third micro LEDs 101, 102, 103. Accordingly, the first to third micro LEDs 101, 102, 103 may be protected from impact applied from an outside.

The energy harvesting member 200 may be formed on the upper surface 501 of the sub-substrate 50. The energy harvesting member 200 may be arranged to surround the first to third micro LEDs 101, 102, 103 as shown in FIG. 3 to absorb light emitted from the first to third micro LEDs 101, 102, 103. In this case, the energy harvesting member 200 may be arranged spaced apart from the first to third micro LEDs 101, 102, 103 at a given interval to absorb light emitted from sides of the first to third micro LEDs 101, 102, 103.

The energy harvesting member 200 may include a PN junction N-type semiconductor layer 201 and P-type semiconductor layer 203. The energy harvesting member 200 may be formed in a quadrangle when viewed in a plan view. A side surface 2011 of the N-type semiconductor layer 201 may correspond to the inner side of the energy harvesting member 200. The side surface 2011 of the N-type semiconductor layer 201 may absorb light emitted from the first to third micro LEDs 101, 102, 103. A side surface 2031 of the P-type semiconductor layer 203 may correspond to the outer side of the energy harvesting member 200.

With reference to FIG. 5, light emitted from the first to third micro LEDs 101, 102, 103 may be absorbed into the side surface 2011 of the N-type semiconductor layer 201. Accordingly, free electrons of the N-type semiconductor layer 201 are transferred to holes of the P-type semiconductor layer 203 and thus an electromotive force may be generated. The electromotive force having a low voltage may be boosted by passing through a voltage boosting circuit 70 and then be stored in a condenser 90. As the above, the energy harvesting member 200 may convert light energy emitted from the first to third micro LEDs 101, 102, 103 to electric energy by an photoelectric effect and then store it.

The energy harvesting member 200 may increase an amount of light absorption of the N-type semiconductor layer 201 as a height H2 thereof becomes higher. In this case, the height H2 of the energy harvesting member 200 may be formed in a height of at least about twice a height H1 of the first to third micro LEDs 101, 102, 103. Here, the height H1 of the first to third micro LEDs 101, 102, 103 may be an average height of the first to third micro LEDs 101, 102, 103.

The energy harvesting member 200 may harvest electric energy by absorbing external light even in the case of the first to third micro LEDs 101, 102, 103. For example, the micro LED disposed at a partial region of the entire region of the display panel 10 may be off according to images displayed on the display panel 10. In this case, the energy harvesting member 200 may harvest electric energy through a photoelectric effect by absorbing external light (for example, indoor lighting light, sun light, etc.) via the upper surface 2012 of the N-type semiconductor layer 201 as shown FIG. 4. As the above, the electric energy harvested by the energy harvesting member 200 may be used for standby power of the display device 1 or be used for power generation.

The N-type semiconductor layer 201 may be disposed on an inner side of energy harvesting member 200 and the P-type semiconductor layer 203 may be disposed on an outer side thereof. Accordingly, a boundary surface of the N-type semiconductor layer 201 and the P-type semiconductor layer 203 may be arranged to be approximately perpendicular with respect to an arrangement direction of the sub-substrate 50. The energy harvesting member 200 having the boundary surface as the above may maximize and/or increase an amount of light absorption emitted from the first to third micro LEDs 101, 102, 103 because the side surface 2011 of the N-type semiconductor layer 201 may form an entire inner side of the energy harvesting member 200. Also, the boundary surface of the N-type semiconductor layer 201 and the P-type semiconductor layer 203 is simply formed and thus a production yield of parts may increase.

With reference to FIG. 4, the upper surface 2012 of the N-type semiconductor layer 201 may form part of the upper surface of the energy harvesting member 200. The upper surface 2012 of the N-type semiconductor layer 201 may be formed to correspond to the entire upper surface of the energy harvesting member. In this case, the upper surface 2012 of the N-type semiconductor layer 201 may be wider or be maximized or increased while a thickness T of the energy harvesting member 200 is not extended. Hereinafter, structures of widening an absorption area of external light and of increasing energy absorption by widening a boundary surface of the N-type semiconductor layer 201 and P-type semiconductor layer 203 are described with reference to the drawings.

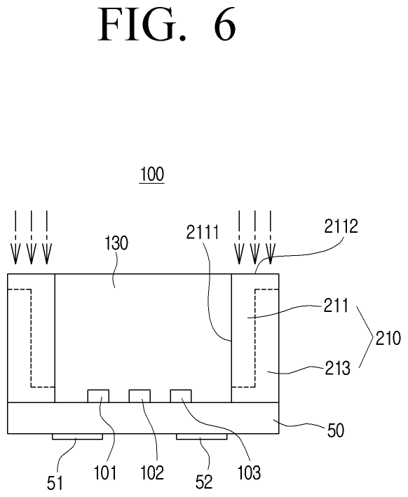

FIGS. 6, 7, 8, 9, 10, 11 and 12 are longitudinal sectional views illustrating a light emitting diode unit according to various embodiments. The light emitting diode unit 100 shown in FIGS. 6, 7, 8, 9, 10, 11 and 12 (which may be referred to as FIGS. 6 to 12) is provided with the same reference numeral with respect to the same configuration as that of the aforementioned light emitting diode unit 100 (see FIGS. 3 and 4). The description thereof is omitted.

With reference to FIG. 6, the N-type semiconductor layer 201 of the light emitting diode unit 100 may be formed such that an upper surface 2112 extended to the side surface 2111 of the N-type semiconductor layer 201 corresponds to the entire upper surface of the light emitting diode unit 100.

The N-type semiconductor layer 211 may be formed in a shape corresponding to that of the P-type semiconductor layer 213. For example, the boundary surface of the N-type semiconductor layer 211 and the P-type semiconductor layer 213 may include an upper horizontal plane, a lower horizontal plane, and a vertical plane connecting the upper horizontal plane and the lower horizontal plane.

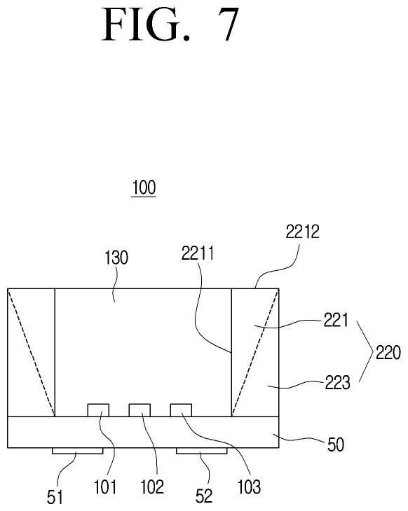

With reference to FIG. 7, a boundary surface of a N-type semiconductor layer 221 and a P-type semiconductor layer 223 of an energy harvesting member 220 of the light emitting diode unit 100 may be arranged in an approximately diagonal direction. Accordingly, a side surface 2211 of the N-type semiconductor layer 221 may correspond to an entire inner side of the energy harvesting member 220. An upper surface 2212 of the energy harvesting member 220 may correspond to an entire upper surface of the energy harvesting member 220.

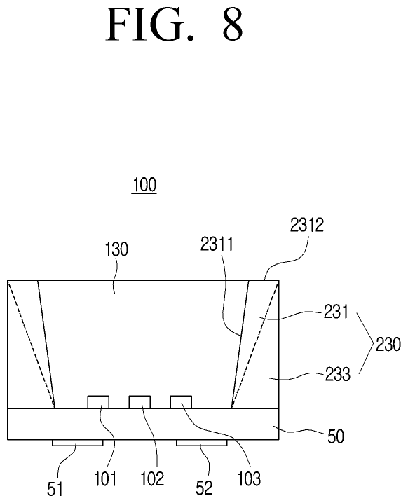

With reference to FIG. 8, an energy harvesting member 230 of a light harvesting member 230 is similar with the aforementioned energy harvesting member 220 (see FIG. 7) wherein a boundary surface of a N-type semiconductor layer 231 and a P-type semiconductor layer 233 may be disposed in an approximately diagonal direction.

In this case, a side surface 2311 of the N-type semiconductor layer 231 may be obliquely disposed. Accordingly, a space formed by the energy harvesting member 230 may form a shape such that the top thereof is wide and the bottom thereof is narrow. In this case, an angle of light emitted from the light emitting diode unit 100 may be greater than that of the aforementioned light emitting diode unit 100 (see FIG. 7). The upper surface 2311 of the N-type semiconductor layer 231 may correspond to an entire upper surface of the energy harvesting member 230.

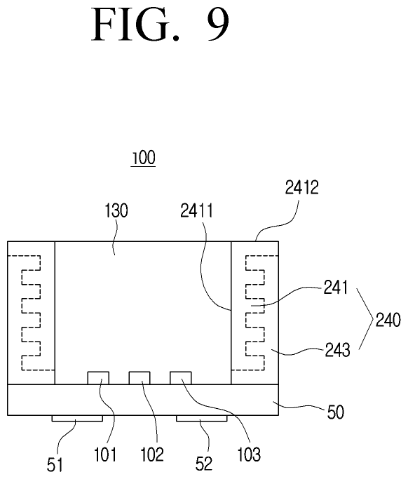

With reference to FIG. 9, a boundary surface of a N-type semiconductor layer 241 and a P-type semiconductor layer 243 of an energy harvesting member 240 of the light emitting diode unit 100 may be disposed in an approximately uneven shape. In this case, a boundary surface of the N-type semiconductor layer 241 and the P-type semiconductor layer 243 may be formed in a straight line. The boundary surface of the N-type semiconductor layer 241 and the P-type semiconductor layer 243 may be wider than those of the aforementioned energy harvesting members 200, 210, 220, 230. Therefore, an amount of energy harvesting capable of being obtained by the energy harvesting member 240 may increase.

A side surface 2411 of the N-type semiconductor layer 241 may correspond to an entire inner side of the energy harvesting member 240. An upper surface 2412 of the energy harvesting member 240 may correspond to an entire upper surface of the energy harvesting member 240.

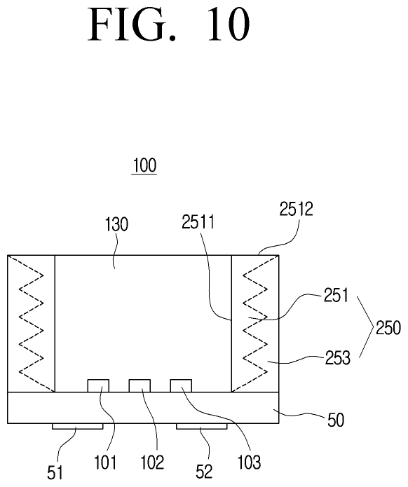

With reference to FIG. 10, a boundary surface of a N-type semiconductor layer 251 and a P-type semiconductor layer 253 of an energy harvesting member 250 of the light emitting diode unit 100 may be disposed in a shape of zigzags approximately. In this case, the boundary surface of the N-type semiconductor layer 251 and the P-type semiconductor layer 253 may be wider than those of the aforementioned energy harvesting members 200, 210, 220, 230. Therefore, an amount of energy harvesting capable of being obtained by the energy harvesting member 250 may increase.

A side surface 2511 of the N-type semiconductor layer 251 may correspond to an entire inner side of the energy harvesting member 250. An upper surface 2512 of the energy harvesting member 250 may correspond to an entire upper surface of the energy harvesting member 250.

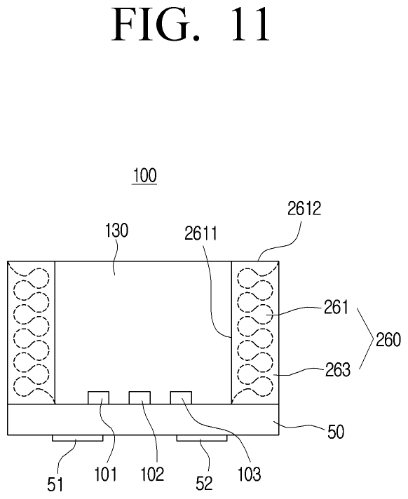

With reference to FIG. 11, a boundary surface of a N-type semiconductor layer 261 and a P-type semiconductor layer 263 of an energy harvesting member 260 of the light emitting diode unit 100 may be disposed in an approximately uneven shape. In this case, the boundary surface of the N-type semiconductor layer 261 and the P-type semiconductor layer 263 may be formed in a shape such that protrusions having a curved shape are alternately engaged with one another. The boundary surface of the N-type semiconductor layer 261 and the P-type semiconductor layer 263 may be wider than those of the aforementioned energy harvesting members 200, 210, 220, 230. Therefore, an amount of energy harvesting capable of being obtained by the energy harvesting member 260 may increase. Also, if light is absorbed into the N-type semiconductor layer 261 of the energy harvesting member 260, when free electrons in the center of an inside of protrusions having a curved shape of the N-type semiconductor layer 261 move to protrusions having a curved shape of the P-type semiconductor layer 263, the free electrons may travel in any direction. Therefore, a photoelectric effect may be enhanced.

A side surface 2611 of the N-type semiconductor layer 261 may correspond to an entire inner side of the energy harvesting member 260. An upper surface 2612 of the energy harvesting member 260 may correspond to an entire upper surface of the energy harvesting member 260.

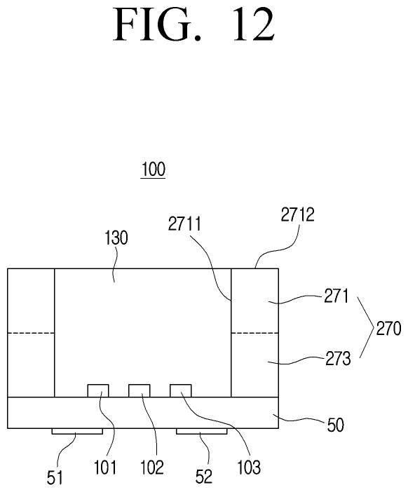

With reference to FIG. 12, a N-type semiconductor layer 271 and a P-type semiconductor layer 273 of an energy harvesting member 270 of the light emitting diode unit 100 may be disposed above and below. For example, the P-type semiconductor layer 273 may be disposed on an upper surface of the sub-substrate 50 and the N-type semiconductor layer 271 may be disposed on an upper surface of the P-type semiconductor layer 273. In this case, a side surface 2711 of the N-type semiconductor layer 271 may correspond to an upper portion of an inner side of the energy harvesting member 250. An upper surface 2712 of the energy harvesting member 270 may correspond to an entire upper surface of the energy harvesting member 270.

An upper surface 2711 of the N-type semiconductor layer 271 of the energy harvesting member 270 having the boundary surface as the above may form an entire upper surface of the energy harvesting member 270. Thus, an amount of absorption of external light may be maximized and/or increased. Also, the boundary surface of the N-type semiconductor layer 271 and the P-type semiconductor layer 273 is simply formed and thus a production yield of parts may increase.

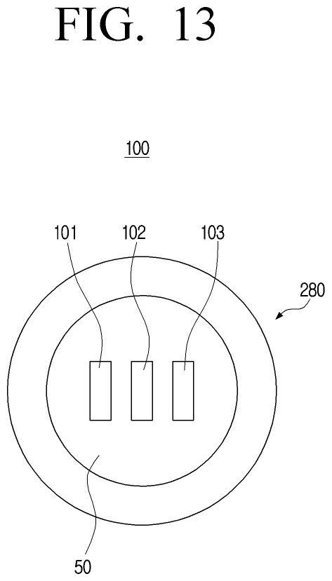

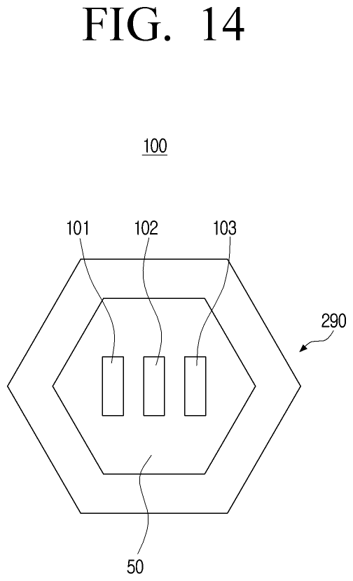

FIGS. 13 and 14 are diagrams illustrating plan views of examples of energy harvesting members of light emitting diode units thereof formed in a circle and a polygon, respectively according to various embodiments.

With reference to FIG. 13, an energy harvesting member 280 of the light emitting diode unit 100 may be formed in a circle approximately when viewed in a plan view but it is not limited thereto. For example, the energy harvesting member 280 may be formed in a shape of an ellipse or a closed curve when viewed in a plan view.

With reference to FIG. 14, an energy harvesting member 290 of the light emitting diode unit 100 may be formed in a hexagon approximately when viewed in a plan view but it is not limited thereto. For example, the energy harvesting member 290 may be formed in a polygon such as a pentagon, a heptagon, and an octagon.

As shown in FIGS. 13 and 14, the boundaries of N-type semiconductor layers and P-type semiconductor layers of the energy harvesting members 280, 290 may correspond to one of boundary surfaces of the aforementioned energy harvesting members 200, 210, 220, 230, 240, 250, 260, 270.

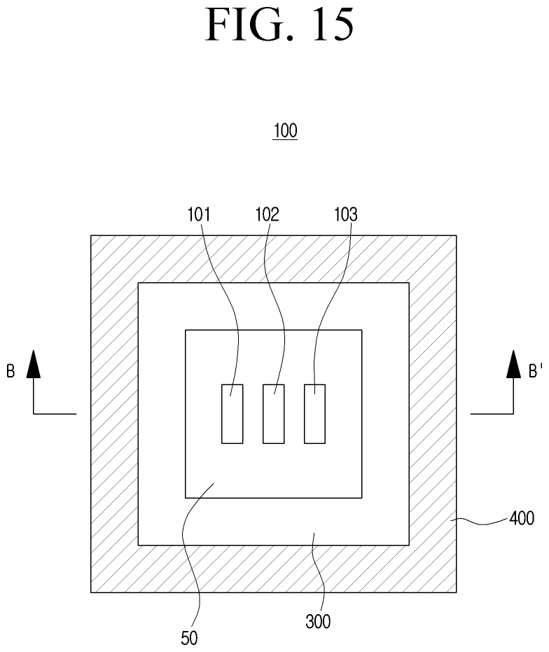

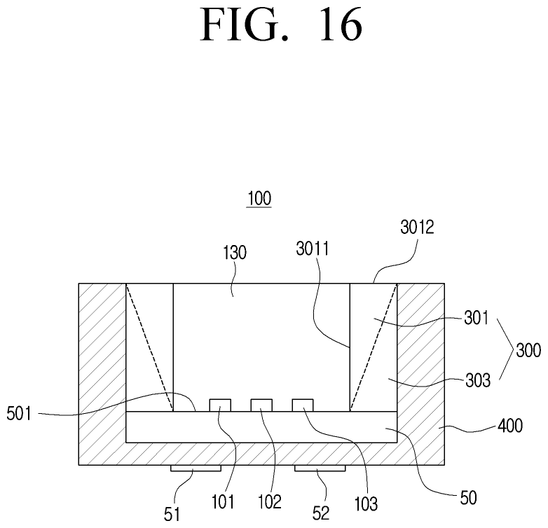

FIG. 15 is a diagram illustrating a plan view of a light emitting diode unit according to various embodiments. FIG. 16 is a longitudinal sectional view taken along line B-B′ in FIG. 15 according to various embodiments. In describing the light emitting diode unit 100 shown in FIGS. 15 and 16, the same reference numeral is given to the same configuration as that of the aforementioned light emitting diode unit 100 (see FIGS. 3 and 4) and the description thereof may not be repeated.

With reference to FIG. 15, the light emitting diode unit 100 may include a frame 400 surrounding an energy harvesting member 300.

The frame 400 may be formed with a synthetic resin material and have a black based-dark color. The frame 400 may prevent and/or reduce light leakage of the light emitting diode unit 100 and protect the energy harvesting member 300 and the first to third micro LEDs 101, 102, 103 from external impact.

When the light emitting diode unit 100 is arranged on the substrate 40, the frame 400 may be close to the frame 400 of the adjacent light emitting diode unit 100. In this case, the frame 400 may perform a role of a black matrix because it has a black based-color.

With reference to FIG. 16, the sub-substrate 50 may be disposed on an inside bottom of the frame 400 and the plurality of electrode pads 51, 52 are disposed on a lower surface thereof. In this case, the plurality of electrode pads 51, 52 may be electrically connected to the sub-substrates 50 through wiring formed in via holes (not shown) penetrating the frame 400.

A boundary surface of a N-type semiconductor layer 301 and a p-type semiconductor layer 303 of the energy harvesting member 300 of the light emitting diode unit 100 may be disposed in an approximately diagonal direction. In this case, a side surface 3011 of the N-type semiconductor layer 301 may correspond to an entire inner side of the energy harvesting member 300. An upper surface 3012 of the N-type semiconductor layer 301 may correspond to an entire upper surface of the energy harvesting member 300.

The energy harvesting member 300 is not limited to the fact that the boundary surface of the N-type semiconductor layer 301 and the p-type semiconductor layer 303 thereof is disposed in a diagonal direction. For example, the energy harvesting member 300 may have one of boundaries of the aforementioned energy harvesting members 200, 210, 230, 240, 250, 260.

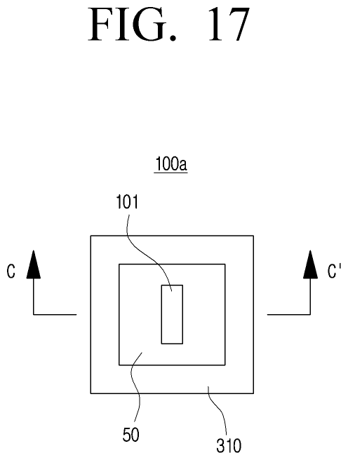

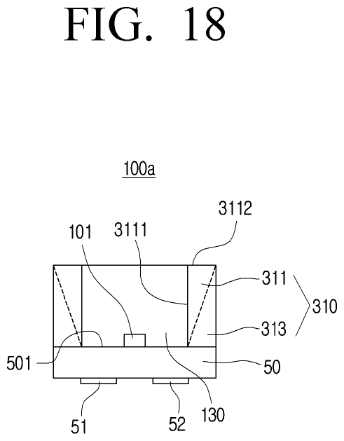

FIG. 17 is a diagram illustrating a plan view of the light emitting diode unit according to various embodiments. FIG. 18 is a longitudinal sectional view taken along line C-C′ in FIG. 17 according to various embodiments. In describing a light emitting diode unit 100a shown in FIGS. 17 and 18, the same reference numeral is given to the same configuration as that of the aforementioned light emitting diode unit 100 (see FIGS. 3 and 4) and the description thereof may not be repeated.

With reference to FIG. 17, the light emitting diode unit 100a may include one micro LED 101. For example, the light emitting diode unit 100a may correspond to one sub-pixel. Therefore, if the light emitting diode 100a is used, a light emitting diode including a red micro LED, a light emitting diode including a green micro LED, and a light emitting diode including a blue micro LED may be included so as to implement one pixel. Thus, a size of the light emitting diode unit 100a including one micro LED may be smaller than that of the aforementioned light emitting diode unit.

The light emitting diode unit 100a may include an energy harvesting member 310 and may harvest electric energy by absorbing light or absorbing external light emitted from the micro LED 101. A boundary surface of a N-type semiconductor layer 311 and a P-type semiconductor layer 313 of the energy harvesting member 310 of the light emitting diode unit 100a may be disposed in an approximately diagonal direction. In this case, a side surface 3111 of the N-type semiconductor layer 311 may correspond to an entire inner side of the energy harvesting member 310. An upper surface 3112 of the N-type semiconductor layer 311 may correspond to an entire upper surface of the energy harvesting member 310.

The energy harvesting member 310 is not limited to the fact that the boundary surface of the N-type semiconductor layer 311 and the P-type semiconductor layer 313 is disposed in a diagonal direction. For example, the energy harvesting member 310 may have one of boundaries of the aforementioned energy harvesting members 200, 210, 230, 240, 250, 260.

As the above, the present disclosure is described with reference to various example embodiments, and it will be understood that the various example embodiments are intended to be illustrative, not limiting. The terminologies used herein are for description and are not to be understood to be intended to limit the present disclosure. It will be further understood by those skilled in the art that various modifications and variants of the present disclosure may be made without departing from the true spirit and full scope of the disclosure, including the appended claims and their equivalents. It will also be understood that any of the embodiment(s) described herein may be used in conjunction with any other embodiment(s) described herein.

What is claimed is:

1. A light emitting diode unit, comprising:
a substrate;
a light emitting diode arranged on the substrate; and
an energy harvesting member comprising a semiconductor layer surrounding the light emitting diode and configured to generate electric energy by absorbing light energy emitted from the light emitting diode,
wherein an inner side of the energy harvesting member is spaced apart from the light emitting diode.

2. The light emitting diode unit of claim 1, wherein a height of the energy harvesting member is greater than a height of the light emitting diode.

3. The light emitting diode unit of claim 1, wherein the energy harvesting member comprises:
an N-type semiconductor layer comprising the inner side of the energy harvesting member; and
a P-type semiconductor layer comprising an outer side of the energy harvesting member and in contact with the N-type semiconductor layer.

4. The light emitting diode unit of claim 3, wherein an upper surface of the N-type semiconductor layer forms an entire upper surface of the energy harvesting member.

5. The light emitting diode unit of claim 3, wherein a boundary surface of the N-type semiconductor layer and the P-type semiconductor layer of the energy harvesting member is disposed in a diagonal direction.

6. The light emitting diode unit of claim 3, wherein the boundary surface of the N-type semiconductor layer and the P-type semiconductor layer of the energy harvesting member has an uneven in shape.

7. The light emitting diode unit of claim 3, wherein the boundary surface of the N-type semiconductor layer and the P-type semiconductor layer of the energy harvesting member has a zigzag in shape.

8. The light emitting diode unit of claim 1, wherein the energy harvesting member is polygonal when viewed in a plan view.

9. The light emitting diode unit of claim 1, wherein the energy harvesting member is a form of a closed curve when viewed in a plan view.

10. The light emitting diode unit of claim 1, wherein the energy harvesting member is circular or elliptical when viewed in a plan view.

11. The light emitting diode unit of claim 1, wherein the light emitting diode is provided in multiple numbers.

12. The light emitting diode unit of claim 1, wherein the light emitting diode comprises a micro LED.

13. A display module, comprising:
a first substrate on which a plurality of thin film transistors are provided; and
a plurality of light emitting diode units comprising a light emitting diode are arranged on the first substrates,
wherein each of the plurality of light emitting diode units comprises:
a second substrate;
a light emitting diode arranged on the second substrate; and
an energy harvesting member comprising a semiconductor layer surrounding a side surface of the light emitting diode and spaced apart from the light emitting diode.

14. The display module of claim 13, wherein a height of the energy harvesting member is greater than a height of the light emitting diode.

15. The display module of claim 13, wherein the energy harvesting member comprises:
an N-type semiconductor layer comprising an inner side of the energy harvesting member; and
a P-type semiconductor layer comprising an outer side of the energy harvesting member and in contact with the N-type semiconductor layer,
wherein an upper surface of the N-type semiconductor layer forms an entire upper surface of the energy harvesting member.
